(19) United States
(12) Patent Application Publication
(10) Pub. No.: US 2012/0104492 A1
(43) Pub. Date: May 3, 2012

(54) LOW ON-RESISTANCE RESURF MOS TRANSISTOR

(75) Inventors: Chien-Wen CHU, Taoyuan County (TW); Wing-Chor CHAN, Hsinchu City (TW); Shyi-Yuan WU, Hsinchu City (TW)

(73) Assignee: MACRONIX INTERNATIONAL CO., LTD., Hsin-Chu (TW)

(21) Appl. No.: 12/915,589

(22) Filed: Oct. 29, 2010

(51) Int. Cl. H01L 29/78; H01L 21/336

(52) U.S. Cl. 257/335; 438/286; 257/E21.417; 257/E29.256; 257/492

(57) ABSTRACT

The present invention relates to a low on-resistance RESURF MOS transistor, comprising: a drift region; two isolation regions formed on the drift region; a first-doping-type layer disposed between the two isolation regions; and a second-doping-type layer disposed below the first-doping-type layer.

### FIELD OF THE INVENTION

The present invention relates to a MOS transistor, and more particularly to a low on-resistance RESURF MOS transistor.

### BACKGROUND OF THE INVENTION

In recent years, lateral diffused MOSFET transistors (aka LDMOS) are widely used for operating under high voltage in very large scale integrated circuit (VLSI). For ascending the operating voltage of devices, the concept of REduced SURface Field (aka RESURF) have been widely used for power semiconductor devices development because it gives the best trade-off breakdown voltage and Rdson.

FIG. 1 is a cross section of a conventional double RESURF n-channel LDMOS transistor 10. The double RESURF n-channel LDMOS transistor 10 has a P-type substrate 11, a high voltage N well (HVNW) 12, an N-type well 121, an N+ source region 124, a P-base 123, an N+ drain region 122, a P+ contact region 125, a P-well 13, a P+ region 131, isolation regions 14, a gate electrode 15 and a P-top layer 16.

Due to the implanted P-top layer 16 in the upper portion of the High Voltage N-Well (HVNW) 12, there is an additional depletion region occurring at the junction between the P-top layer 16 and the HVNW 12. As a result, the breakdown voltage of the double RESURF n-channel LDMOS transistor 10 is accordingly increased. However, on the other hand, a drawback that the surface on-resistance of the device is increased is correspondingly induced since the carrier (electron) concentration at the upper portion of the HVNW 12 is decreased owing to the implanted P-top layer 16. Not only double RESURF n-channel LDMOS transistor 10, but the conventional multi RESURF with P-TOP layer design would also have the aforementioned drawback.

Therefore the applicant attempts to deal with the above situation encountered in the prior art.

### SUMMARY OF THE INVENTION

In view of the prior art, although a high breakdown voltage is provided by the P-top layer implanted in the conventional double or multi RESURF LDMOS for operating with high voltage, the P-top layer also causes the surface resistance of the RESURF LDMOS increases. Therefore, the present invention provides a RESURF MOS transistor not only has a high breakdown voltage but also provides a lower on-resistance than the conventional double RESURF LDMOS. The MOS provided by the present invention is in possession of two properties, the high breakdown voltage and the low resistance, at the same time.

In accordance with the first aspect of the present invention, a MOS device is provided. The MOS device includes: a drift region; two isolation regions formed on the drift region; a first-doping-type layer disposed between the two isolation regions; and a second-doping-type layer disposed below the first-doping-type layer.

Preferably, the first-doping-type layer is doped with a first-type impurity and the second-doping-type layer is doped with a second-type impurity, and the MOS device further comprises a gate, a drain region doped with the second-type impurity and a source region doped with the second-type impurity.

Preferably, the first-type impurity is a P-type impurity and the second-type impurity is an N-type impurity.

Preferably, the drift region is a high voltage well doped with the second-type impurity, and the source region and drain region are included in the high voltage well.

Preferably, the first-type impurity is an N-type impurity and the second-type impurity is a P-type impurity.

Preferably, the MOS device further comprising: a substrate doped with the P-type impurity; and an N-buried layer (NBL) disposed between the high voltage well and the substrate.

Preferably, the MOS device is formed by one being selected from a group consisting of an SOI process, an N-EPI process, a P-EPI process and a non-EPI process.

Preferably, the MOS device further includes an OD region separating the two isolation regions, wherein the first doping type layer is disposed at the OD region.

Preferably, the two isolation regions are formed by one being selected from a group consisting of a local oxidation of silicon (LOCOS) process, a shallow trench isolation (STI) process and a deep trench isolation (DTI) process.

Preferably, the first-doping-type layer and the second-doping-type layer are self-aligned by the two isolation regions.

In accordance with the second aspect of the present invention, a method for forming a MOS device is provided. The method includes steps of: providing a drift region; forming two isolation regions on the drift region; forming a first-doping-type layer between the two isolation regions; and forming a second-doping-type layer below the first-doping-type layer.

Preferably, the first-doping-type layer is doped with a first-type impurity and the second-doping-type layer is lightly doped with a second-type impurity, and the method further comprises steps of: providing a gate, a drain region doped with the second-type impurity and a source region doped with the second-type impurity.

Preferably, the first-type impurity is a P-type impurity and the second-type impurity is an N-type impurity.

Preferably, the drift region is a high voltage well doped with the second-type impurity, and the source region and drain region are provided in the high voltage well.

Preferably, the first-type impurity is an N-type impurity and the second-type impurity is a P-type impurity.

Preferably, the method further includes steps of: providing a substrate doped with the P-type impurity; and providing an N-buried layer (NBL) between the high voltage well and the substrate.

Preferably, the MOS device is formed by one being selected from a group consisting of an SOI process, an N-EPI process, a P-EPI process and a non-EPI process.

Preferably, the method further includes a step of providing an OD (Oxide Definition) region separating the two isolation regions, wherein the first doping type layer is located at the OD region.

Preferably, the two isolation regions are formed by one being selected from a group consisting of a local oxidation of silicon (LOCOS) process, a shallow trench isolation (STI) process and a deep trench isolation (DTI) process.

Preferably, the first-doping-type layer and the second-doping-type layer are self-aligned by the two isolation regions.

In accordance with the third aspect of the present invention, a MOS device is provided. The MOS device includes: two isolation regions; a first-doping-type layer disposed between the two isolation regions; and a second-doping-type layer disposed below the first-doping-type layer.

### BRIEF DESCRIPTION OF THE DRAWINGS

The foregoing and other features and advantages of the present invention will be more clearly understood through the following descriptions with reference to the drawings, wherein:

FIG. 1 is a cross section of the prior art;

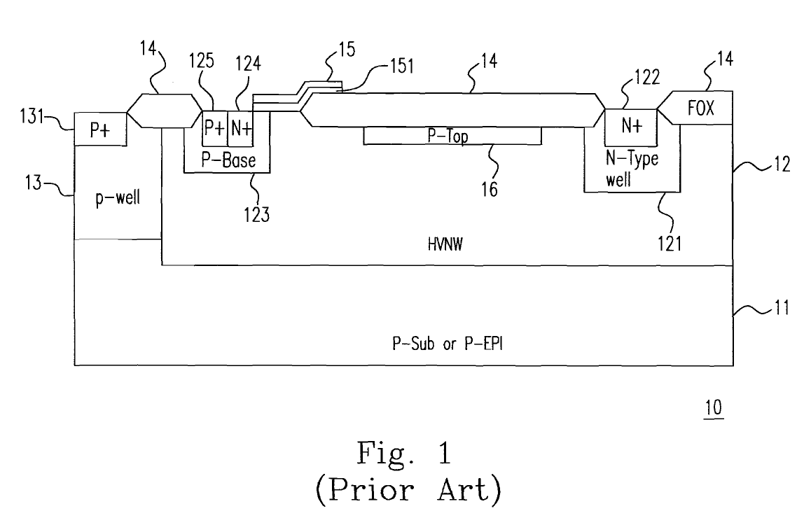

FIG. 2 is a cross section illustrating the first embodiment of the present invention;

FIG. 3 is a cross section illustrating the second embodiment according to the present invention;

FIG. 4 is a cross section illustrating another embodiment according to the present invention;

FIG. 5 is a cross section illustrating another embodiment according to the present invention;

FIG. 6 is a cross section illustrating an embodiment according to the present invention under the design of the double RESURF LDMOS with multi rings;

FIG. 7 is a cross section illustrating another embodiment according to the present invention under the design of the double RESURF LDMOS with multi rings;

FIG. 8 is a cross section illustrating yet another embodiment according to the present invention under the design of the double RESURF LDMOS with multi rings; and

FIG. 9 is a cross section illustrating another embodiment according to the present invention under the design of the double RESURF LDMOS with multi rings.

### DETAIL DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

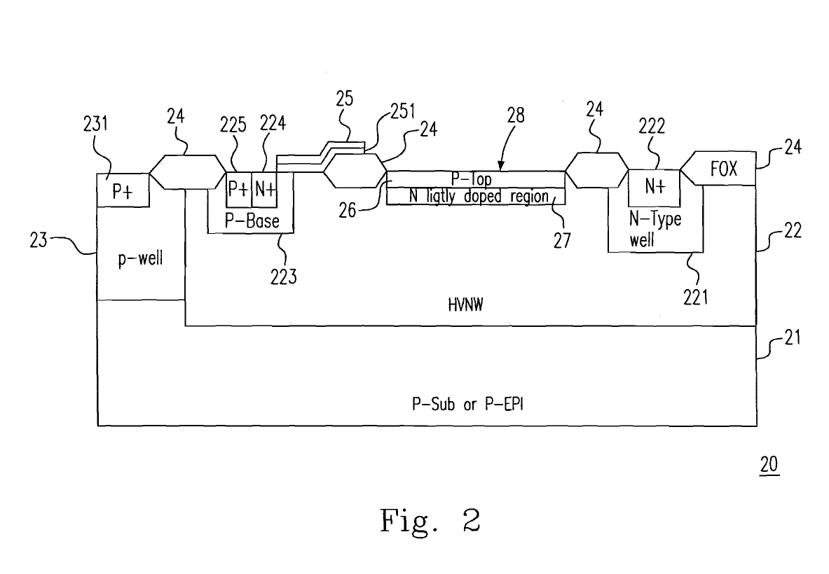

Please refer to FIG. 2, which is a cross section of an n-channel LDMOS for illustrating the first embodiment of the low on-resistance double RESURF MOS transistor according to the present invention. As shown in FIG. 2, the LDMOS 20 has a substrate 21, a high voltage N well (HVNW) 22, an N-type well 221, an N+ source region 224, a P-base 223, an N+ drain region 222, a P+ contact region 225, a P-well 23, a P+ region 231, isolation regions 24, a gate electrode 25, a gate oxide 251, a P-top layer 26, and an N lightly doped region 27.

The HVNW 22 and P-well 23 are formed in the upper portion of the substrate 21, wherein the substrate 21 is preferably a P-substrate or a P-EPI, and the HVNW 22 is used as a drift region of the LDMOS 20. The P-base 223, including the P+ contact region 225 and the N+ source region 224, and the N-type well 221, including the N+ drain region 222, are formed within the HVNW 22. The isolation regions 24, preferably being field oxides (FOX), are formed on the upper surface of the HVNW 22 by a Local Oxidation of Silicon (LOCOS) process, a Shallow Trench Isolation (STI) process or a Deep Trench Isolation (DTI) process.

The OD (Oxide Definition) region 28 is configured between the two isolation regions 24, and includes a P-top layer 26 and an N lightly doped region 27. Since the doping type of the P-top layer 26 opposite to that of the HVNW 22 can cause impediment on the carriers drifting in the drift region (HVNW 22), the resistance near the P-top layer 26 is thus increased. Therefore, the P-top layer 26 is first implanted at the OD region 28, where none of carriers pass. In addition, the N lightly doped region 27 is then implanted below the P-top layer 26 so as to compensate the concentration of the HVNW 22 reduced by the P-top layer 26. The P-top layer 26 and the N lightly doped region 27 are self-aligned by the two isolation regions 24.

In such a configuration, it could be found that the on-resistance (Rdson) of the n-channel LDMOS 20 of the present invention is greatly improved as illustrated in Table I.

TABLE I
Present Invention V.S. Conventional Double RESURF LDMOS

| Comparative Item | Breakdown Voltage | Rdson |
|---|---|---|
| Variation Percentage | −5.87% | −40.09% |

It could be seen that the on-resistance of the n-channel LDMOS 20 is reduced by 40.09% compared with the on-resistance of the conventional double RESURF LDMOS. That is, the carrier drifting ability of the present invention is better than that of the conventional double RESURF LDMOS. Therefore, the present invention not only has a high breakdown voltage comparable to the conventional RESURF LDMOS transistor but also keeps a low on-resistance, and is in possession of both the breakdown voltage and the on-resistance.

In addition, the above-mentioned LDMOS transistors could be formed by a plurality of processes, such as an N-EPI process, a P-EPI process or non-EPI process.

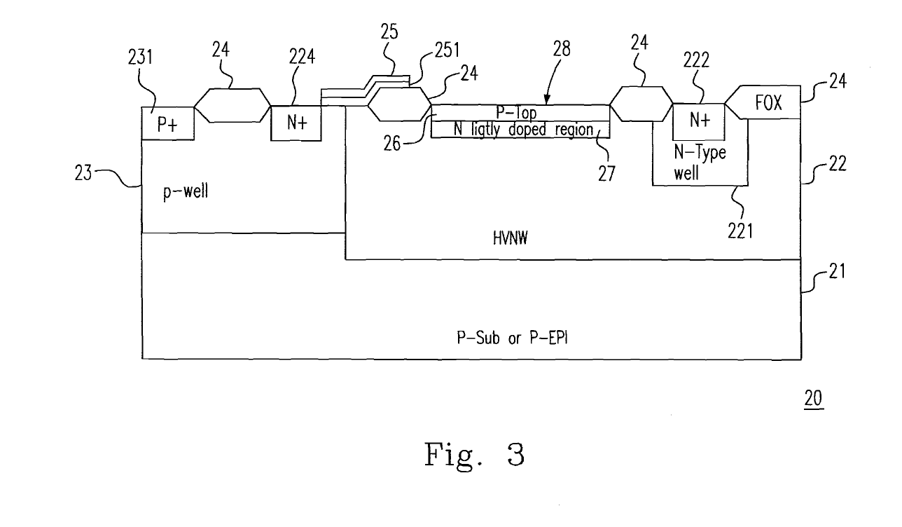

Certainly, the present invention could be further applied on the RESURF LDMOS by slightly altering the structure in the preceding first embodiment. Referring to FIG. 3, the second embodiment of the invention is provided. The structural difference between the second and the first embodiment resides in that both the N+ source region 224 and the P+ region 231 in FIG. 3 are surrounded by the P-well 23 due to a different process. All the other reference numerals in FIG. 3 are identical to those of FIG. 2.

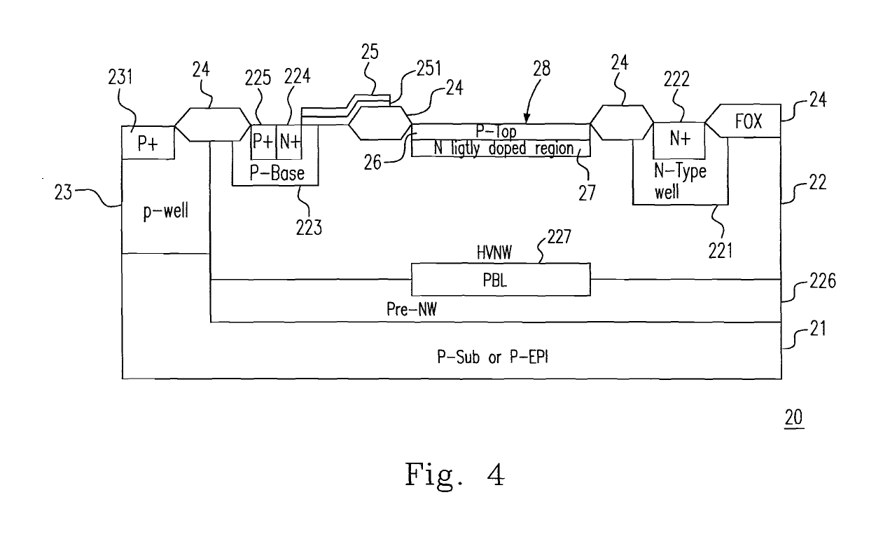

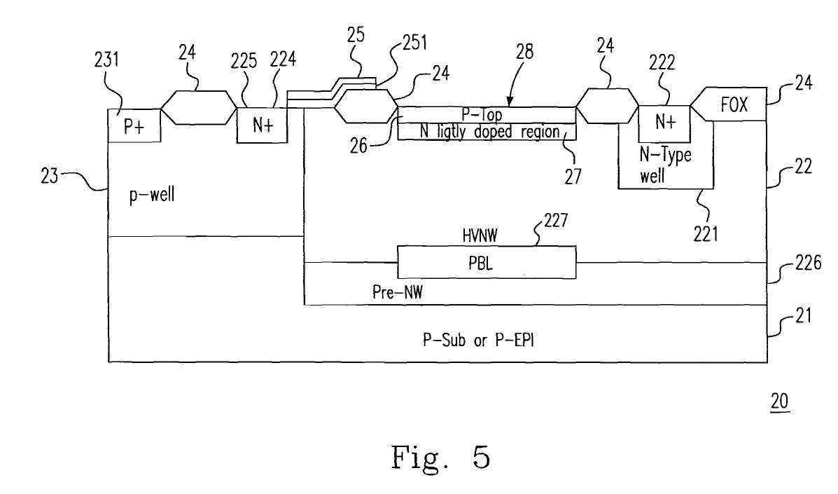

FIG. 4 and FIG. 5 are embodiments respectively similar to FIG. 2 and FIG. 3, and illustrate that the present invention applied on RESURF LDMOS with different structure, wherein a Pre-N well 226 is formed between the HVNW 22 and the substrate 21, and a P-buried layer (PBL) 227 is formed between the HVNW 22 and the Pre-N well 226.

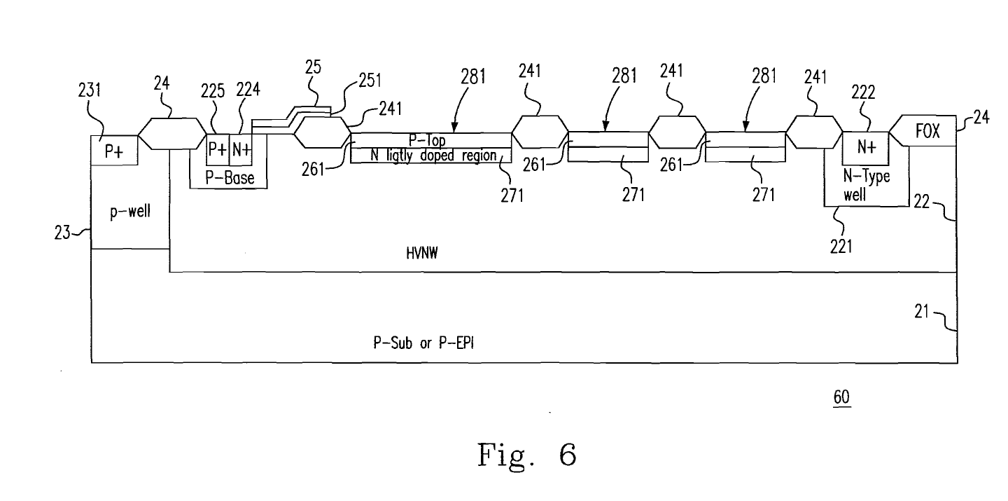

The present invention could also be applied on double RESURF LDMOS with multi rings. FIG. 6 shows a double RESURF LDMOS 60 with multi rings modified from the double RESURF LDMOS in FIG. 2. It can be seen that there are totally four isolation regions 241 divided by three OD regions 281 at which three P-top layers 261 with three N lightly doped regions 271 implanted therebelow are respectively implanted. The double RESURF LDMOS in FIG. 6 is so called double RESURF LDMOS with multi P-rings due to the multi P-top layers.

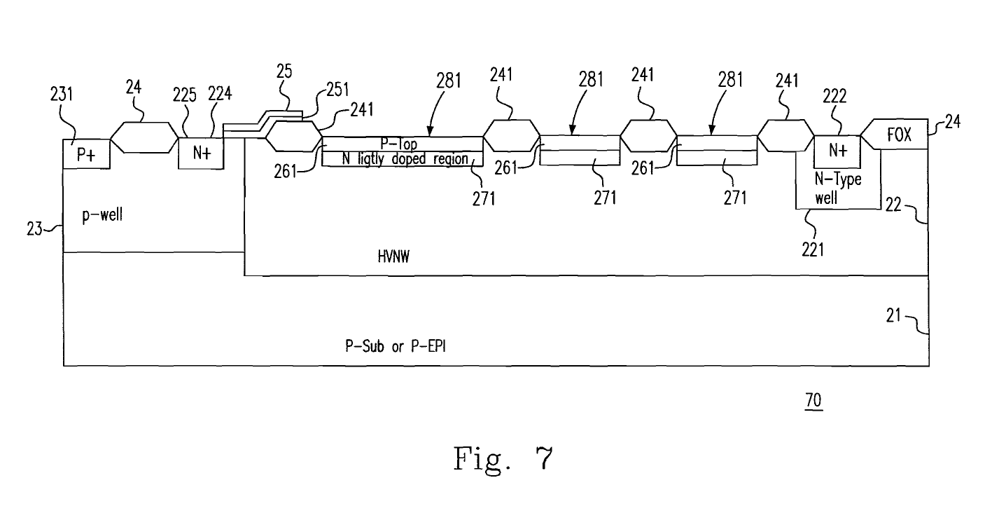

Similarly, FIG. 7 shows another double RESURF LDMOS 70 with multi P-rings modified from the double RESURF LDMOS in FIG. 3. The double RESURF LDMOS 70 also has four isolation regions 241 divided by three OD regions 281, and three P-top layers 261 are respectively implanted at the three OD regions 281 with three N lightly doped regions 271 implanted therebelow. It should be noticed that the amount of the isolation regions 241, P-top layers 261 and N lightly doped regions 271 is not limited by the above-mentioned embodiments.

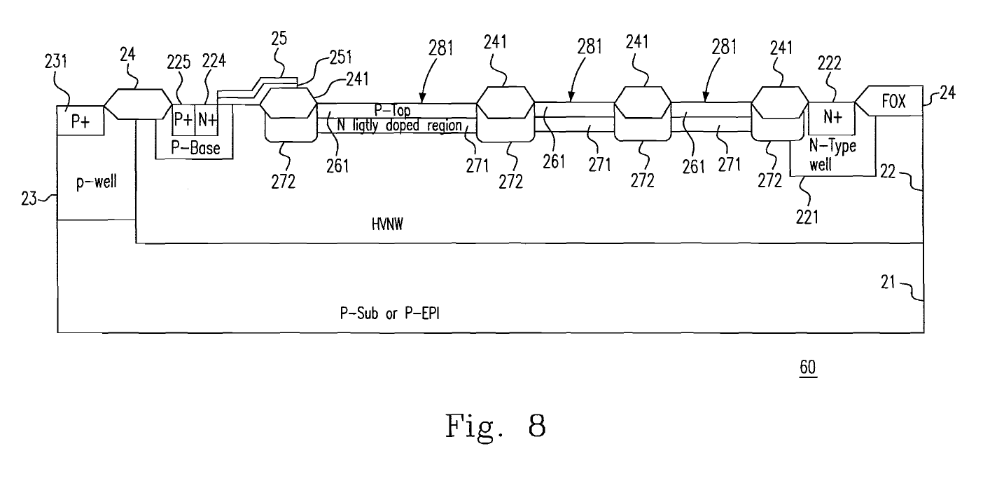

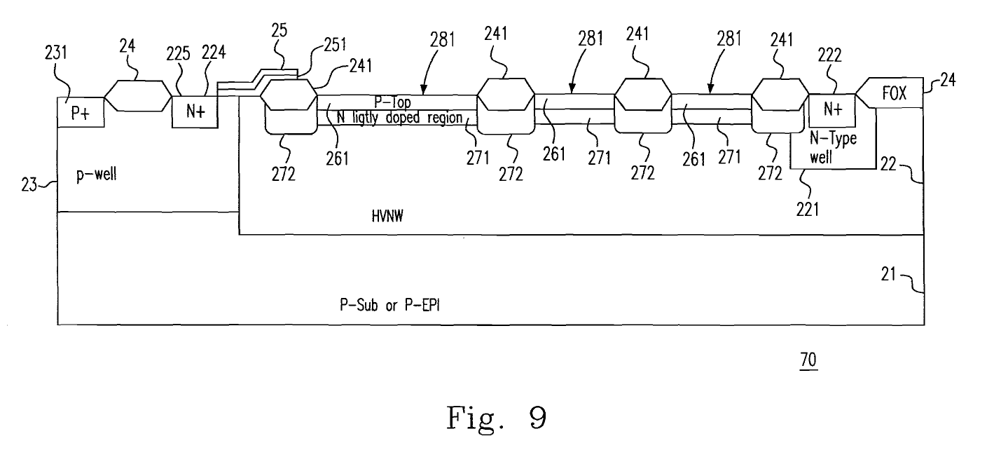

FIG. 8 and FIG. 9 further illustrate two other embodiments according to the present invention, and are respectively similar to FIG. 6 and FIG. 7 except that there are second N lightly doped regions 272 implanted below the isolation regions 241.

It could be understood by one skilled in the art that the doping types, namely the N and P types, in the above-mentioned embodiments could be exchanged. However, there would be an additional N-buried layer (NBL) between the high voltage P well and the P-substrate for separating the high voltage P well from the substrate, such that the P-substrate would not directly “see” the high voltage applied on the high voltage P well.

It could also be known to one skilled in the art that the invention can also be applied to an EDMOS.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A MOS device, comprising:
a drift region;
two isolation regions formed on the drift region;
a first-doping-type layer disposed between the two isolation regions; and
a second-doping-type layer disposed below the first-doping-type layer.

2. The MOS device as claimed in claim 1, wherein the first-doping-type layer is doped with a first-type impurity and the second-doping-type layer is doped with a second-type impurity, and the MOS device further comprises a gate, a drain region doped with the second-type impurity and a source region doped with the second-type impurity.

3. The MOS device as claimed in claim 2, wherein the first-type impurity is a P-type impurity and the second-type impurity is an N-type impurity.

4. The MOS device as claimed in claim 2, wherein the drift region is a high voltage well doped with the second-type impurity, and the source region and drain region are included in the high voltage well.

5. The MOS device as claimed in claim 4, wherein the first-type impurity is an N-type impurity and the second-type impurity is a P-type impurity.

6. The MOS device as claimed in claim 5 further comprising:
a substrate doped with the P-type impurity; and
an N-buried layer (NBL) disposed between the high voltage well and the substrate.

7. The MOS device as claimed in claim 1, wherein the MOS device is formed by one being selected from a group consisting of an SOI process, an N-EPI process, a P-EPI process and a non-EPI process.

8. The MOS device as claimed in claim 1 further comprising an OD region separating the two isolation regions, wherein the first doping type layer is disposed at the OD region.

9. The MOS device as claimed in claim 1, wherein the two isolation regions are formed by one being selected from a group consisting of a local oxidation of silicon (LOCOS) process, a shallow trench isolation (STI) process and a deep trench isolation (DTI) process.

10. The MOS device as claimed in claim 1, wherein the first-doping-type layer and the second-doping-type layer are self-aligned by the two isolation regions.

11. A method for forming a MOS device, comprising steps of:
providing a drift region;
forming two isolation regions on the drift region;
forming a first-doping-type layer between the two isolation regions; and
forming a second-doping-type layer below the first-doping-type layer.

12. The method as claimed in claim 11, wherein the first-doping-type layer is doped with a first-type impurity and the second-doping-type layer is lightly doped with a second-type impurity, and the method further comprises steps of: providing a gate, a drain region doped with the second-type impurity and a source region doped with the second-type impurity.

13. The method as claimed in claim 12, wherein the first-type impurity is a P-type impurity and the second-type impurity is an N-type impurity.

14. The method as claimed in claim 12, wherein the drift region is a high voltage well doped with the second-type impurity, and the source region and drain region are provided in the high voltage well.

15. The method as claimed in claim 14, wherein the first-type impurity is an N-type impurity and the second-type impurity is a P-type impurity.

16. The method as claimed in claim 15 further comprising steps of:
providing a substrate doped with the P-type impurity; and
providing an N-buried layer (NBL) between the high voltage well and the substrate.

17. The method as claimed in claim 11, wherein the MOS device is formed by one being selected from a group consisting of an SOI process, an N-EPI process, a P-EPI process and a non-EPI process.

18. The method as claimed in claim 11 further comprising a step of providing an OD region separating the two isolation regions, wherein the first doping type layer is located at the OD region.

19. The method as claimed in claim 11, wherein the two isolation regions are formed by one being selected from a group consisting of a local oxidation of silicon (LOCOS) process, a shallow trench isolation (STI) process and a deep trench isolation (DTI) process.

20. The method as claimed in claim 11, wherein the first-doping-type layer and the second-doping-type layer are self-aligned by the two isolation regions.

21. A MOS device, comprising:
two isolation regions;
a first-doping-type layer disposed between the two isolation regions; and
a second-doping-type layer disposed below the first-doping-type layer.
